(19) United States
(12) Patent Application Publication
(10) Pub. No.: US 2026/0130032 A1
(43) Pub. Date: May 7, 2026

(54) DISPLAY APPARATUS

(71) Applicant: AUO Corporation, Hsinchu City (TW)

(72) Inventors: Sheng-Miao Huang, Hsinchu City (TW); Chan-Jui Liu, Hsinchu City (TW)

(73) Assignee: AUO Corporation, Hsinchu City (TW)

(21) Appl. No.: 19/230,101

(22) Filed: Jun. 6, 2025

(30) Foreign Application Priority Data
Nov. 6, 2024 (TW) 113142465

(51) Int. Cl. H10H 29/49; H01L 25/16; H10H 20/821; H10H 20/831; H10H 29/855

(52) U.S. Cl. CPC H10H 29/49; H10H 20/821; H10H 20/8312; H10H 29/855; H10W 90/00

(57) ABSTRACT

A display apparatus includes a driving backplane, a first light-emitting element, an island-shaped insulation structure, and a conductive pattern disposed on island-shaped insulation structure and electrically connected to a second electrode of first light-emitting element. The driving backplane has a common electrode, a sub-pixel driving circuit, a first pad, a second pad, and a third pad. The first and second pads are electrically connected to the sub-pixel driving circuit. The third pad is electrically connected to the common electrode. A first electrode of the first light-emitting element is bonded to the first pad of driving backplane. Island-shaped insulation structure is disposed on first light-emitting element. Second and third pads are located outside island-shaped insulation structure, which includes first and second insulation layers. First insulation layer covers first light emitting element. Second insulation layer is disposed on first insulation layer. First portion of second insulation layer extends outside first insulation layer.

### CROSS-REFERENCE TO RELATED APPLICATION

This application claims the priority benefit of Taiwan application serial no. 113142465, filed on Nov. 6, 2024. The entirety of the above-mentioned patent application is hereby incorporated by reference herein and made a part of this specification.

### BACKGROUND

### Technical Field

The disclosure relates to an optoelectronic apparatus, and particularly relates to a display apparatus.

### Related Art

With the advancement of display technology, the development of the panel industry is no longer just pursuing large size and high production capacity utilization, but is moving toward presenting higher level panel image quality as a goal. The current trend of panel development is gradually shifting from backlight emission to active emission, mainly because active emission panels have advantages such as being thin and light, flexible, wide color gamut, wide viewing angle, high contrast, high resolution, which may present excellent panel image quality and are suitable for more diversified product applications. Among various active emission displays, micro light-emitting diode displays further have advantages that organic light-emitting diode displays do not have, such as local dimming, high brightness, longer service life, and thus have also become the main development technology for the future panel industry.

To improve the yield of micro light-emitting diode displays, in addition to disposing micro light-emitting diodes on the main pads of the driving backplane, additional micro light-emitting diodes are further disposed on the repair pads of the driving backplane. After forming multiple micro light-emitting diodes on the main pads and repair pads, a planarization layer is formed to facilitate the subsequent formation of conductive patterns. However, once the planarization layer is formed, the micro light-emitting diode display may not be easily repaired.

### SUMMARY

The disclosure provides a display apparatus, which is convenient for repair.

The display apparatus of the disclosure includes a driving backplane, a first light-emitting element, an island-shaped insulation structure, and a conductive pattern. The driving backplane has a common electrode, a sub-pixel driving circuit, a first pad, a second pad, and a third pad. The third pad is structurally separated from the first pad and the second pad. The first pad and the second pad are electrically connected to the sub-pixel driving circuit, and the third pad is electrically connected to the common electrode. The first light-emitting element has a first type semiconductor layer, a second type semiconductor layer, a first active layer disposed between the first type semiconductor layer and the second type semiconductor layer, a first electrode electrically connected to the first type semiconductor layer, and a second electrode electrically connected to the second type semiconductor layer. The first electrode and the second electrode are respectively disposed on opposite sides of the first active layer, and the first electrode of the first light-emitting element is bonded to the first pad of the driving backplane. The island-shaped insulation structure is disposed on the first light-emitting element. The second pad and the third pad are located outside the island-shaped insulation structure. The island-shaped insulation structure includes a first insulation layer and a second insulation layer. The first insulation layer covers the first light-emitting element. The second insulation layer is disposed on the first insulation layer and has an opening located on the second electrode of the first light-emitting element. A first portion of the second insulation layer extends outside the first insulation layer. The conductive pattern is disposed on the island-shaped insulation structure. A first end of the conductive pattern fills into the opening of the second insulation layer of the island-shaped insulation structure and is electrically connected to the second electrode of the first light-emitting element. A second end of the conductive pattern extends from the first portion of the second insulation layer of the island-shaped insulation structure to outside the island-shaped insulation structure and is electrically connected to the common electrode of the driving backplane.

### BRIEF DESCRIPTION OF THE DRAWINGS

FIG. 1 is a top view schematic diagram of a display apparatus according to an embodiment of the disclosure.

FIG. 2 is a cross-sectional view schematic diagram of the display apparatus according to an embodiment of the disclosure.

FIG. 3 is a cross-sectional view schematic diagram of the display apparatus according to an embodiment of the disclosure.

FIG. 4 is a cross-sectional view schematic diagram of the display apparatus according to an embodiment of the disclosure.

### DESCRIPTION OF THE EMBODIMENTS

Reference will now be made in detail to exemplary embodiments of the disclosure, examples of the embodiments are illustrated in the accompanying drawings. Wherever possible, the same reference numerals are used in the drawings and descriptions to refer to the same or similar parts.

It should be understood that when an element such as a layer, film, region, or substrate is referred to as being “on” or “connected to” another element, it may be directly on or connected to the other element, or intervening elements may also be present. In contrast, when an element is referred to as being “directly on” or “directly connected to” another element, there are no intervening elements present. As used herein, “connected” may refer to physical and/or electrical connection. Furthermore, “electrical connection” or “coupling” may exist between two elements with other elements present therebetween.

The terms “about,” “approximately,” or “substantially” as used herein include the stated value and mean values within an acceptable deviation range as determined by ordinary skilled persons in the art, considering the specific quantity of the measurements and errors associated with the measurements (that is, limitations of the measurement system). For example, “about” may represent within one or more standard deviations of the stated value, or within ±30%, ±20%, ±10%, ±5% of the stated value. Furthermore, the terms “approximately,” “about,” or “substantially” used herein may refer to acceptable ranges of deviation or standard deviations selected based on optical properties, etching properties, or other characteristics, rather than applying a single standard deviation uniformly to all properties.

Unless otherwise defined, all terms (including technical and scientific terms) used herein have the same meaning as commonly understood by ordinary skilled persons in the field to which the disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

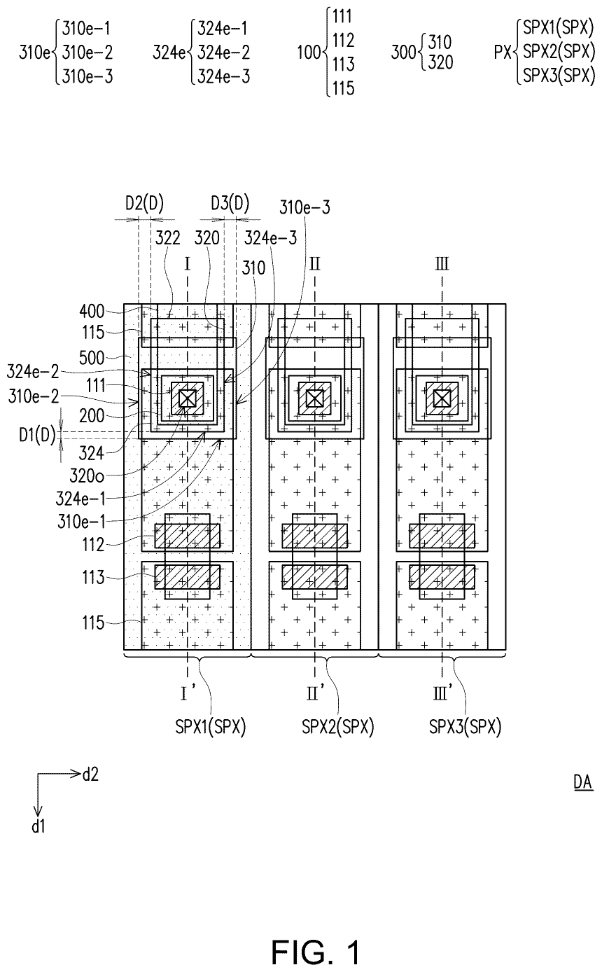

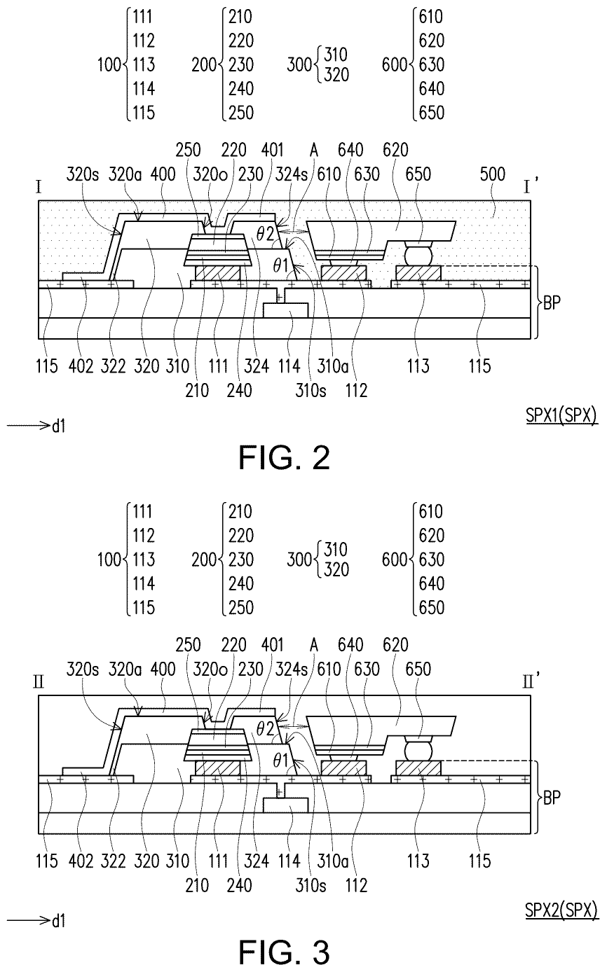

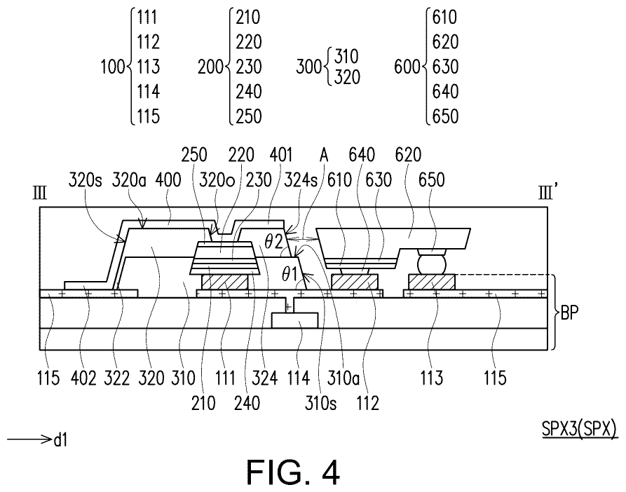

FIG. 1 is a top view schematic diagram of a display apparatus according to an embodiment of the disclosure. FIG. 2 is a cross-sectional view schematic diagram of the display apparatus according to an embodiment of the disclosure. FIG. 2 corresponds to a cross-sectional line I-I′ in FIG. 1. FIG. 3 is a cross-sectional view schematic diagram of the display apparatus according to an embodiment of the disclosure. FIG. 3 corresponds to a cross-sectional line II-II′ in FIG. 1. FIG. 4 is a cross-sectional view schematic diagram of the display apparatus according to an embodiment of the disclosure. FIG. 4 corresponds to a cross-sectional line III-III′ in FIG. 1. FIG. 1 omits a sub-pixel driving circuit 114 in FIG. 2, FIG. 3, and FIG. 4.

FIG. 1 shows a pixel PX of a display apparatus DA, in which one pixel PX includes multiple sub-pixels SPX. FIG. 2, FIG. 3 and FIG. 4 respectively show cross-sections of the multiple sub-pixels SPX of one pixel PX in FIG. 1. The display apparatus DA includes multiple pixels PX arranged in an array. Persons with ordinary knowledge in the art should be able to implement the entire display apparatus DA based on one pixel PX illustrated in FIG. 1 to FIG. 4 and the following description. Therefore, other pixels PX of the display apparatus DA are not repeatedly illustrated.

Referring to FIG. 1, FIG. 2, FIG. 3, and FIG. 4, the display apparatus DA includes the multiple pixels PX arranged in the array. Each pixel PX includes the multiple sub-pixels SPX. Each sub-pixel SPX includes a sub-pixel driving structure 100 of a driving backplane BP. Each sub-pixel driving structure 100 includes a first pad 111, a second pad 112, a third pad 113, a sub-pixel driving circuit 114, and a common electrode 115, in which the third pad 113 is structurally separated from the first pad 111 and the second pad 112, the first pad 111 and the second pad 112 are electrically connected to the sub-pixel driving circuit 114, and the third pad 113 is electrically connected to the common electrode 115.

For example, in some embodiments, each sub-pixel driving circuit 114 may include a first transistor (not shown), a second transistor (not shown), and a capacitor (not shown), in which a first end of the first transistor is electrically connected to a corresponding data line (not shown), a control end of the first transistor is electrically connected to a corresponding gate line (not shown), a second end of the first transistor is electrically connected to a control end of the second transistor, a first end of the second transistor is electrically connected to a corresponding power line (not shown), the capacitor is electrically connected between the second end of the first transistor and the first end of the second transistor, and a second end of the second transistor is electrically connected to the first pad 111 and the second pad 112 of the same sub-pixel driving structure 100, but the disclosure is not limited thereto.

Each sub-pixel SPX further includes a first light-emitting element 200. The first light-emitting element 200 has a first type semiconductor layer 210, a second type semiconductor layer 220, a first active layer 230 disposed between the first type semiconductor layer 210 and the second type semiconductor layer 220, a first electrode 240 electrically connected to the first type semiconductor layer 210, and a second electrode 250 electrically connected to the second type semiconductor layer 220, in which the first electrode 240 and the second electrode 250 are respectively disposed on opposite sides of the first active layer 230, and the first electrode 240 of the first light-emitting element 200 is bonded to the first pad 111 of the sub-pixel driving structure 100 of the same sub-pixel SPX. In brief, the first light-emitting element 200 is a vertical light-emitting diode, and the lower electrode of the vertical light-emitting diode is bonded to a corresponding first pad 111. For example, in some embodiments, the first light-emitting element 200 may be a micro light-emitting diode (μLED), but the disclosure is not limited thereto.

Each sub-pixel SPX further includes an island-shaped insulation structure 300 disposed on the first light-emitting element 200 of the same sub-pixel SPX. The second pad 112 and the third pad 113 of the same sub-pixel SPX are located outside the island-shaped insulation structure 300. That is, the island-shaped insulation structure 300 does not cover the second pad 112 and the third pad 113 used for repair.

Each sub-pixel SPX further includes a conductive pattern 400 disposed on the island-shaped insulation structure 300. The conductive pattern 400 electrically connects the second electrode 250 of the first light-emitting element 200 of the same sub-pixel SPX and the common electrode 115 of the same sub-pixel SPX. The conductive pattern 400 is, for example, a transparent conductive pattern. In some embodiments, the material of the conductive pattern 400 may include metal oxide, such as indium tin oxide, indium zinc oxide, aluminum tin oxide, aluminum zinc oxide, indium germanium zinc oxide, or other suitable oxides, or a stacked layer of at least two of the above, but the disclosure is not limited thereto.

In some embodiments, each sub-pixel SPX further includes an optical structure 500 covering the island-shaped insulation structure 300, the second pad 112, and the third pad 113 of the same sub-pixel SPX. The optical structure 500 of each sub-pixel SPX may be a color conversion pattern, a transparent pattern, or a scattering pattern. The color conversion pattern may change the wavelength of incident light. The transparent pattern has low haze, and the transparent pattern may not include scattering particles. The scattering pattern has high haze, and the scattering pattern may include scattering particles.

For example, in some embodiments, the multiple sub-pixels SPX of a pixel PX may include one sub-pixel SPX1, one sub-pixel SPX2, and one sub-pixel SPX3, in which the first light-emitting element 200 of the sub-pixel SPX1 may be used to emit blue light, the optical structure 500 of the sub-pixel SPX1 may be a color conversion pattern that converts blue light to red light, the first light-emitting element 200 of the sub-pixel SPX2 may be used to emit green light, the optical structure 500 of the sub-pixel SPX2 may be a transparent pattern or a scattering pattern that allows green light to pass through without changing the wavelength thereof, the first light-emitting element 200 of the sub-pixel SPX3 may be used to emit blue light, the optical structure 500 of the sub-pixel SPX3 may be a transparent pattern or a scattering pattern that allows blue light to pass through without changing the wavelength thereof, but the disclosure is not limited thereto.

It is worth noting that the island-shaped insulation structure 300 of each sub-pixel SPX includes a first insulation layer 310 and a second insulation layer 320. The first insulation layer 310 covers the first light-emitting element 200 of the same sub-pixel SPX. The second insulation layer 320 of the island-shaped insulation structure 300 is disposed on the first insulation layer 310 and has an opening 320o located on the second electrode 250 of the first light-emitting element 200. A first portion 322 of the second insulation layer 320 extends outside the first insulation layer 310. A first end 401 of the conductive pattern 400 fills into the opening 320o of the second insulation layer 320 of the island-shaped insulation structure 300 and is electrically connected to the second electrode 250 of the first light-emitting element 200 of the same sub-pixel SPX. A second end 402 of the conductive pattern 400 extends from the first portion 322 of the second insulation layer 320 of the island-shaped insulation structure 300 to outside the island-shaped insulation structure 300 and is electrically connected to the common electrode 115. That is to say, the conductive pattern 400 is essentially climbing on a side wall 320s of the same insulation layer (that is, the second insulation layer 320) of the island-shaped insulation structure 300, where the side wall 320s is not divided into multiple slope sections, and thus the conductive pattern 400 is less likely to have disconnection issues.

Referring to FIG. 1 and FIG. 2, in some embodiments, a portion of the first insulation layer 310 and the first portion 322 of the second insulation layer 320 of the island-shaped insulation structure 300 may cover a portion of the common electrode 115. In some embodiments, the second insulation layer 320 of the island-shaped insulation structure 300 has a top surface 320a facing away from the driving backplane BP, and the top surface 320a of the second insulation layer 320 of the island-shaped insulation structure 300 is higher than the second electrode 250 of the first light-emitting element 200.

Referring to FIG. 1, in some embodiments, in a top view of the display apparatus DA, the first portion 322 of the second insulation layer 320 is located outside the area of the first insulation layer 310, the second portion 324 of the second insulation layer 320 is located within the area of the first insulation layer 310, and an edge 324e of the second portion 324 of the second insulation layer 320 is separated from an edge 310e of the first insulation layer 310 by a distance D. For example, in some embodiments, the distance D may fall within a range of 0.5 μm to 3.5 μm, but the disclosure is not limited thereto.

Referring to FIG. 1, specifically, in some embodiments, the first pad 111, the second pad 112, and the third pad 113 are arranged in a first direction d1 parallel to the driving backplane BP (shown in FIG. 2), the edge 324e of the second portion 324 of the second insulation layer 320 includes a first sub-edge 324e-1 intersecting with the first direction d1, the edge 310e of the first insulation layer 310 includes a first sub-edge 310e-1 intersecting with the first direction d1 and not covered by the second insulation layer 320, and the first sub-edge 310e-1 of the first insulation layer 310 is separated from the first sub-edge 324e-1 of the second insulation layer 320 by a first distance D1 in the first direction d1. In some embodiments, a second direction d2 is parallel to the driving backplane BP (shown in FIG. 2) and intersects with the first direction d1, the edge 324e of the second portion 324 of the second insulation layer 320 further includes a second sub-edge 324e-2 and a third sub-edge 324e-3 arranged in the second direction d2 and opposite to each other, the edge 310e of the first insulation layer 310 further includes a second sub-edge 310e-2 and a third sub-edge 310e-3 arranged in the second direction d2, opposite to each other, and not covered by the second insulation layer 320, the second sub-edge 324e-2 of the second insulation layer 320 is separated from the second sub-edge 310e-2 of the first insulation layer 310 by a second distance D2, and the third sub-edge 324e-3 of the second insulation layer 320 is separated from the third sub-edge 310e-3 of the first insulation layer 310 by a third distance D3. In some embodiments, the first distance D1, the second distance D2, and the third distance D3 may fall within a range of 0.5 μm to 3.5 μm, but the disclosure is not limited thereto.

Referring to FIG. 1 and FIG. 2, in some embodiments, the first insulation layer 310 has a side wall 310s defining the edge 310e of the first insulation layer 310, the first insulation layer 310 has a top surface 310a facing away from the driving backplane BP, the second insulation layer 320 has a side wall 324s defining the edge 324e of the second portion 324 of the second insulation layer 320, and the optical structure 500 contacts the side wall 310s of the first insulation layer 310, the top surface 310a of the first insulation layer 310, and the side wall 324s of the second insulation layer 320. That is, in some embodiments, a portion (that is, the second portion 324) of the second insulation layer 320 is recessed within the edge 310e of the first insulation layer 310, and the second insulation layer 320 does not cover a portion of the top surface 310a of the first insulation layer 310. Thereby, when forming the optical structure 500 on the driving backplane BP, the optical structure 500 may contact a discontinuous slope formed by the side wall 310s of the first insulation layer 310, the top surface 310a of the first insulation layer 310, and the side wall 324s of the second insulation layer 320, and thus increasing the filling rate of the optical structure 500.

In some embodiments, the side wall 310s of the first insulation layer 310 may form a first angle θ1 with the driving backplane BP, the side wall 324s of the second insulation layer 320 forms a second angle θ2 with the top surface 310a of the first insulation layer 310, 45°≤θ1≤90°, 45°≤θ2≤90°, but the disclosure is not limited thereto.

In addition, since the second insulation layer 320 does not cover a portion of the top surface 310a of the first insulation layer 310, a portion of light beam (not shown) emitted from the first light-emitting element 200 may pass through the portion of the top surface 310a of the first insulation layer 310 that is not covered by the second insulation layer 320 without being totally reflected at the interface between the first insulation layer 310 and the second insulation layer 320. Therefore, the light output of the first light-emitting element 200 may be increased. In some embodiments, the first insulation layer 310 of the island-shaped insulation structure 300 has a top surface 310a facing away from the driving backplane BP, and the top surface 310a of the first insulation layer 310 is higher than the first active layer 230 of the first light-emitting element 200.

Referring to FIG. 1 and FIG. 2, in some embodiments, during the manufacturing process of the display apparatus DA, a detection process may be performed after forming the island-shaped insulation structure 300 covering the first light-emitting element 200. If in the detection process, it is found that the first light-emitting element 200 of a certain sub-pixel SPX cannot be driven by the driving backplane BP to emit light normally, then a second light-emitting element 600 used for repair may be bonded to the second pad 112 and the third pad 113 of the sub-pixel SPX to replace the function of the first light-emitting element 200 that cannot emit light. It is worth mentioning that, since the island-shaped insulation structure 300 does not cover the second pad 112 and the third pad 113 used for repair, therefore, when the second light-emitting element 600 used for repair needs to be transferred to the second pad 112 and the third pad 113, the island-shaped insulation structure 300 does not constitute an obstacle.

In some embodiments, the repaired sub-pixel SPX further includes a second light-emitting element 600, in which the second light-emitting element 600 has a third type semiconductor layer 610, a fourth type semiconductor layer 620, a second active layer 630 disposed between the third type semiconductor layer 610 and the fourth type semiconductor layer 620, a third electrode 640 electrically connected to the third type semiconductor layer 610, and a fourth electrode 650 electrically connected to the fourth type semiconductor layer 620, the third electrode 640 and the fourth electrode 650 are disposed on the same side of the second active layer 630, the third electrode 640 and the fourth electrode 650 of the second light-emitting element 600 are respectively bonded to the second pad 112 and the third pad 113 of the sub-pixel SPX that needs repair, the second portion 324 of the second insulation layer 320 of the island-shaped insulation structure 300 is located within the area of the first insulation layer 310, the second insulation layer 320 has a side wall 324s defining the edge 324e of the second portion 324 of the second insulation layer 320, and the side wall 324s of the second insulation layer 320 is separated from the second light-emitting element 600 used for repair by a distance A in the first direction d1 parallel to the driving backplane BP.

What is claimed is:

1. A display apparatus, comprising:
a driving backplane having a common electrode, a sub-pixel driving circuit, a first pad, a second pad, and a third pad, wherein the third pad is structurally separated from the first pad and the second pad, the first pad and the second pad are electrically connected to the sub-pixel driving circuit, and the third pad is electrically connected to the common electrode;
a first light-emitting element, wherein the first light-emitting element has a first type semiconductor layer, a second type semiconductor layer, a first active layer disposed between the first type semiconductor layer and the second type semiconductor layer, a first electrode electrically connected to the first type semiconductor layer, and a second electrode electrically connected to the second type semiconductor layer, the first electrode and the second electrode are respectively disposed on opposite sides of the first active layer, and the first electrode of the first light-emitting element is bonded to the first pad of the driving backplane;
an island-shaped insulation structure disposed on the first light-emitting element, wherein the second pad and the third pad are located outside the island-shaped insulation structure, and the island-shaped insulation structure comprises:
a first insulation layer covering the first light-emitting element; and
a second insulation layer disposed on the first insulation layer, and having an opening located on the second electrode of the first light-emitting element, wherein a first portion of the second insulation layer extends outside the first insulation layer; and
a conductive pattern disposed on the island-shaped insulation structure, wherein a first end of the conductive pattern fills into the opening of the second insulation layer of the island-shaped insulation structure and is electrically connected to the second electrode of the first light-emitting element, and a second end of the conductive pattern extends from the first portion of the second insulation layer of the island-shaped insulation structure to outside the island-shaped insulation structure and is electrically connected to the common electrode of the driving backplane.

2. The display apparatus as claimed in claim 1, wherein in a top view of the display apparatus, a second portion of the second insulation layer is located within an area of the first insulation layer, and an edge of the second portion of the second insulation layer is separated from an edge of the first insulation layer by a distance.

3. The display apparatus as claimed in claim 2, wherein the distance falls within a range of 0.5 μm to 3.5 μm.

4. The display apparatus as claimed in claim 2, wherein the first pad, the second pad, and the third pad are arranged in a first direction parallel to the driving backplane, the edge of the second portion of the second insulation layer comprises a first sub-edge intersecting with the first direction, the edge of the first insulation layer comprises a first sub-edge intersecting with the first direction and not covered by the second insulation layer, and the first sub-edge of the first insulation layer is separated from the first sub-edge of the second insulation layer by a first distance in the first direction.

5. The display apparatus as claimed in claim 4, wherein a second direction is parallel to the driving backplane and intersects with the first direction, the edge of the second portion of the second insulation layer further comprises a second sub-edge and a third sub-edge arranged in the second direction and opposite to each other, the edge of the first insulation layer further comprises a second sub-edge and a third sub-edge arranged in the second direction, opposite to each other, and not covered by the second insulation layer, the second sub-edge of the second insulation layer is separated from the second sub-edge of the first insulation layer by a second distance, and the third sub-edge of the second insulation layer is separated from the third sub-edge of the first insulation layer by a third distance.

6. The display apparatus as claimed in claim 2, further comprising:
an optical structure covering the island-shaped insulation structure, the second pad, and the third pad, wherein the first insulation layer has a side wall defining the edge of the first insulation layer, the first insulation layer has a top surface facing away from the driving backplane, the second insulation layer has a side wall defining the edge of the second portion of the second insulation layer, the optical structure contacts the side wall of the first insulation layer, the top surface of the first insulation layer, and the side wall of the second insulation layer, and the optical structure comprises a color conversion pattern, a transparent pattern, or a scattering pattern.

7. The display apparatus as claimed in claim 1, wherein a portion of the first insulation layer of the island-shaped insulation structure and the first portion of the second insulation layer cover a portion of the common electrode.

8. The display apparatus as claimed in claim 1, wherein the first light-emitting element has the first active layer, the first insulation layer of the island-shaped insulation structure has a top surface facing away from the driving backplane, and the top surface of the first insulation layer is higher than the first active layer of the first light-emitting element.

9. The display apparatus as claimed in claim 1, wherein the second insulation layer of the island-shaped insulation structure has a top surface facing away from the driving backplane, and the top surface of the second insulation layer of the island-shaped insulation structure is higher than the second electrode of the first light-emitting element.

10. The display apparatus as claimed in claim 1, further comprising:
a second light-emitting element, wherein the second light-emitting element has a third type semiconductor layer, a fourth type semiconductor layer, a second active layer disposed between the third type semiconductor layer and the fourth type semiconductor layer, a third electrode electrically connected to the third type semiconductor layer, and a fourth electrode electrically connected to the fourth type semiconductor layer, the third electrode and the fourth electrode are disposed on same side of the second active layer, the third electrode and the fourth electrode of the second light-emitting element are respectively bonded to the second pad and the third pad of the driving backplane, a second portion of the second insulation layer of the island-shaped insulation structure is located within an area of the first insulation layer, the second insulation layer has a side wall defining an edge of the second portion of the second insulation layer, and the side wall of the second insulation layer is separated from the second light-emitting element by a distance in a first direction parallel to the driving backplane.

11. A display apparatus, comprising:
a driving backplane having a common electrode, a sub-pixel driving circuit, a first pad, a second pad, and a third pad, wherein the third pad is structurally separated from the first pad and the second pad, the first pad and the second pad are electrically connected to the sub-pixel driving circuit, and the third pad is electrically connected to the common electrode;
a first light-emitting element, wherein the first light-emitting element has a first type semiconductor layer, a second type semiconductor layer, a first active layer disposed between the first type semiconductor layer and the second type semiconductor layer, a first electrode electrically connected to the first type semiconductor layer, and a second electrode electrically connected to the second type semiconductor layer, the first electrode and the second electrode are respectively disposed on opposite sides of the first active layer, and the first electrode of the first light-emitting element is bonded to the first pad of the driving backplane;
an island-shaped insulation structure disposed on the first light-emitting element, wherein the second pad and the third pad are located outside the island-shaped insulation structure, and the island-shaped insulation structure comprises:
a first insulation layer covering the first light-emitting element; and
a second insulation layer disposed on the first insulation layer, and having an opening located on the second electrode of the first light-emitting element; and
a conductive pattern disposed on the island-shaped insulation structure, wherein a first end of the conductive pattern fills into the opening of the second insulation layer of the island-shaped insulation structure and is electrically connected to the second electrode of the first light-emitting element, and a second end of the conductive pattern extends from the second insulation layer of the island-shaped insulation structure to outside the island-shaped insulation structure and is electrically connected to the common electrode of the driving backplane.

12. The display apparatus as claimed in claim 11, wherein a portion of the first insulation layer of the island-shaped insulation structure and a first portion of the second insulation layer cover a portion of the common electrode.

13. The display apparatus as claimed in claim 11, wherein the first light-emitting element has a first active layer, the first insulation layer of the island-shaped insulation structure has a top surface facing away from the driving backplane, and the top surface of the first insulation layer is higher than the first active layer of the first light-emitting element.

14. The display apparatus as claimed in claim 11, wherein the second insulation layer of the island-shaped insulation structure has a top surface facing away from the driving backplane, and the top surface of the second insulation layer of the island-shaped insulation structure is higher than the second electrode of the first light-emitting element.

15. The display apparatus as claimed in claim 1, further comprising:
a second light-emitting element, wherein the second light-emitting element has a third type semiconductor layer, a fourth type semiconductor layer, a second active layer disposed between the third type semiconductor layer and the fourth type semiconductor layer, a third electrode electrically connected to the third type semiconductor layer, and a fourth electrode electrically connected to the fourth type semiconductor layer, the third electrode and the fourth electrode are disposed on same side of the second active layer, the third electrode and the fourth electrode of the second light-emitting element are respectively bonded to the second pad and the third pad of the driving backplane, a portion of the second insulation layer of the island-shaped insulation structure is located within an area of the first insulation layer, the second insulation layer has a side wall defining an edge of the portion of the second insulation layer, and the side wall of the second insulation layer is separated from the second light-emitting element by a distance in a first direction parallel to the driving backplane.
